(19) United States
(12) Patent Application Publication
(10) Pub. No.: US 2023/0207336 A1
(43) Pub. Date: Jun. 29, 2023

(54) DEVICE FOR SUPPLYING A SOLUTION, APPARATUS FOR PROCESSING A SUBSTRATE AND METHOD OF PROCESSING A SUBSTRATE

(71) Applicant: SEMES CO., LTD., Cheonan-si (KR)

(72) Inventors: Chulnam KIM, Sokcho-si (KR); Sunghun EOM, Hwaseong-si (KR); Ickkyun KIM, Osan-si (KR)

(73) Assignee: SEMES CO., LTD., Cheonan-si (KR)

(21) Appl. No.: 18/145,917

(22) Filed: Dec. 23, 2022

(30) Foreign Application Priority Data
Dec. 27, 2021 (KR) 10-2021-0189056

(51) Int. Cl. H01L 21/67; H01L 21/66

(52) U.S. Cl. CPC H01L 21/67023; H01L 22/10; H01L 21/67253

(57) ABSTRACT

An apparatus for processing a substrate may include a chemical liquid discharging part configured to discharge a chemical liquid having a first specific gravity onto a substrate, a chemical liquid supplying part configured to provide the chemical liquid to the chemical liquid discharging part, a fluid supplying part configured to provide a fluid having a second specific gravity different from the first specific gravity, a chemical liquid supplying part configured to provide a chemical liquid having a second specific gravity different from the first specific gravity, and a monitoring port including a trapping part configured to trap the fluid flowing into the chemical liquid supplying part and a sensing part configured to sense an inflow of the fluid. A heat transfer may be generated between the fluid and the chemical liquid such that the chemical liquid has a desired temperature. The fluid may be trapped at a top portion or a bottom portion of the trapping part in accordance with a difference between the first specific gravity and the second specific gravity.

### CROSS-REFERENCE TO RELATED APPLICATION

This application claims priority to Korean Patent Application No. 2021-0189056 filed on Dec. 27, 2021 in the Korean Intellectual Property Office (KIPO), the contents of which are herein incorporated by reference in its entirety.

### BACKGROUND

### 1. Field

Example embodiments of the invention relate to a device for supplying a solution, an apparatus for processing a substrate and a method of processing a substrate. More particularly, example embodiments of the invention relate to a device for supplying a solution capable of providing a chemical liquid for manufacturing of an integrated circuit device, an apparatus for processing a substrate including such as device for supplying a solution, and a method of processing a substrate using the apparatus for processing a substrate.

### 2. Related Technology

A process for discharging a chemical liquid onto a substrate may be performed in manufacturing processes for an integrated circuit device such as a semiconductor device or a display device. For example, a process for coating a chemical liquid including a photoresist on the substrate may be executed.

The photoresist coated on the substrate has a temperature required according to process conditions, and thus a device for supplying the chemical liquid generally has a double piping configuration. For example, the device for supplying the chemical liquid may include a first line for supplying the chemical liquid including the photoresist and a second line partially enclosing the first line. However, a fluid for allowing the chemical liquid to have the required temperature may be leaked from the second line into the first line and also the fluid may be mixed with the chemical liquid. Such leakage of the fluid and the mixing of the fluid and the chemical liquid may cause failures in the process performed using the chemical liquid.

### SUMMARY

It is one object of the invention to provide a device for supplying a solution capable of providing a chemical liquid having a desired temperature in accordance with process conditions.

It is another object of the invention to provide an apparatus for processing a substrate including a device for supplying a solution capable of providing a chemical liquid having a desired temperature in accordance with process conditions.

It is still another object of the invention to provide a method of processing a substrate performed using an apparatus for processing a substrate including a device for supplying a solution capable of providing a chemical liquid having a desired temperature in accordance with process conditions.

According to an aspect of the invention, there is provided a device for supplying a solution comprising: a fluid supplying part configured to provide a fluid; a chemical liquid supplying part configured to provide a chemical liquid having a specific gravity different from a specific gravity of the fluid; and a monitoring port including a trapping part configured to trap the fluid flowing into the chemical liquid supplying part and a sensing part configured to sense an inflow of the fluid, wherein a heat transfer is generated between the fluid and the chemical liquid, and wherein the fluid is trapped at a top portion or a bottom portion of the trapping part in accordance with a difference between the specific gravity of the fluid and the specific gravity of the chemical liquid.

In example embodiments, the fluid supplying part may be configured to the fluid along a first direction and the chemical liquid may be configured to provide the chemical liquid in a second direction different from the first direction.

In example embodiments, the fluid supplying part may be configured to partially enclose the chemical liquid supplying part or pass through the chemical liquid supplying part.

In some example embodiments, the device for supplying a solution may additionally include a control part configured to stop a supply of the chemical liquid from the chemical liquid supplying part when the inflow of the fluid is identified by the monitoring part.

According to another aspect of the invention, there is provided an apparatus for processing a substrate. The apparatus for processing a substrate may include a chemical liquid discharging part configured to discharge a chemical liquid having a first specific gravity onto a substrate, a chemical liquid supplying part configured to provide the chemical liquid to the chemical liquid discharging part, a fluid supplying part configured to provide a fluid having a second specific gravity different from the first specific gravity, a chemical liquid supplying part configured to provide a chemical liquid having a second specific gravity different from the first specific gravity, and a monitoring port including a trapping part configured to trap the fluid flowing into the chemical liquid supplying part and a sensing part configured to sense an inflow of the fluid. A heat transfer may be generated between the fluid and the chemical liquid such that the chemical liquid has a desired temperature. The fluid may be trapped at a top portion or a bottom portion of the trapping part in accordance with a difference between the first specific gravity and the second specific gravity.

In example embodiments, the chemical liquid discharging part may include a slit nozzle configured to discharge the chemical liquid onto the substrate in a scan manner, or an ink jet head configured to discharge the chemical liquid onto the substrate in a jetting manner.

In example embodiments, the fluid may be trapped at the top portion of the trapping part when the first specific gravity of the chemical liquid is greater than the second specific gravity of the fluid, and the sensing part may be disposed at the top portion of the trapping part.

In some example embodiments, the fluid may be trapped at the bottom portion of the trapping part when the first specific gravity of the chemical liquid is smaller than the second specific gravity of the fluid, and the sensing part may be disposed at the bottom portion of the trapping part.

In example embodiments, the chemical liquid supplying part may be configured to provide the chemical liquid along a first direction and the fluid supplying part may be configured to the fluid in a second direction different from the first direction.

In example embodiments, the fluid supplying part may be configured to partially enclose the chemical liquid supplying part or pass through the chemical liquid supplying part.

In some example embodiments, the apparatus for processing a substrate may additionally include a control part configured to stop a supply of the chemical liquid when the inflow of the fluid is identified by the monitoring part.

In some example embodiments, the control part may be configured to stop a supply of the chemical liquid from the chemical liquid supplying part and a discharge of the chemical liquid from the chemical liquid discharging part.

According to another aspect of the invention, there is provided a method of processing a substrate. In the method of processing a substrate, a chemical liquid having a first specific gravity may be provided to a chemical liquid discharging part from a chemical liquid supplying part, and the chemical liquid may be discharged from the first specific gravity from the chemical liquid discharging part onto a substrate. A fluid having a second specific gravity different from the first specific gravity may be provided from a fluid supplying part to the chemical liquid supplying part. The fluid flowing into the chemical liquid supplying part may be trapped with a trapping part, and an inflow of the fluid in the trapping part may be sensed with a sensing part. A heat transfer may be generated between the fluid and the chemical liquid such that the chemical liquid has a desired temperature. The fluid may be trapped at a top portion or a bottom portion of the trapping part in accordance with a difference between the first specific gravity and the second specific gravity.

In example embodiments, the chemical liquid discharging may discharge the chemical liquid onto the substrate in a scan manner, or a jetting manner.

In example embodiments, the fluid may be trapped at the top portion of the trapping part when the first specific gravity of the chemical liquid is greater than the second specific gravity of the fluid, and the sensing part may be disposed at the top portion of the trapping part.

In some example embodiments, the fluid may be trapped at the bottom portion of the trapping part when the first specific gravity of the chemical liquid is smaller than the second specific gravity of the fluid, and the sensing part may be disposed at the bottom portion of the trapping part.

In example embodiments, the chemical liquid may be provided along a first direction and the fluid may be provided in a second direction different from the first direction.

In example embodiments, the fluid supplying part may partially enclose the chemical liquid supplying part or pass through the chemical liquid supplying part.

In some example embodiments, a supply of the chemical liquid may be stopped when the inflow of the fluid is identified by the sensing part.

In some example embodiments, a supply of the chemical liquid from the chemical liquid supplying part may be stopped and a discharge of the chemical liquid from the chemical liquid discharging part may be stopped.

According to example embodiments, the chemical liquid provided from the chemical liquid supplying part may have the desired temperature using the fluid provided from the fluid supplying part while preventing the fluid and the chemical liquid from being mixed. Further, a failure in the process performed using the chemical liquid may be prevented even though the inflow of the fluid is identified while preventing the mixing of the fluid and the chemical liquid.

### BRIEF DESCRIPTION OF THE DRAWINGS

Example embodiments will be more clearly understood from the following detailed description taken in conjunction with the accompanying drawing. The following figures represent non-limiting, example embodiments as described herein.

FIG. 1 is a schematic cross-sectional view illustrating an apparatus for transferring a substrate in accordance with example embodiments of the invention.

FIGS. 2 and 3 are schematically enlarged cross-sectional views illustrating a monitoring part of a device for supplying a solution in accordance with example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, it will be described an apparatus for supplying a chemical liquid according to example embodiments with reference to the accompanying drawings.

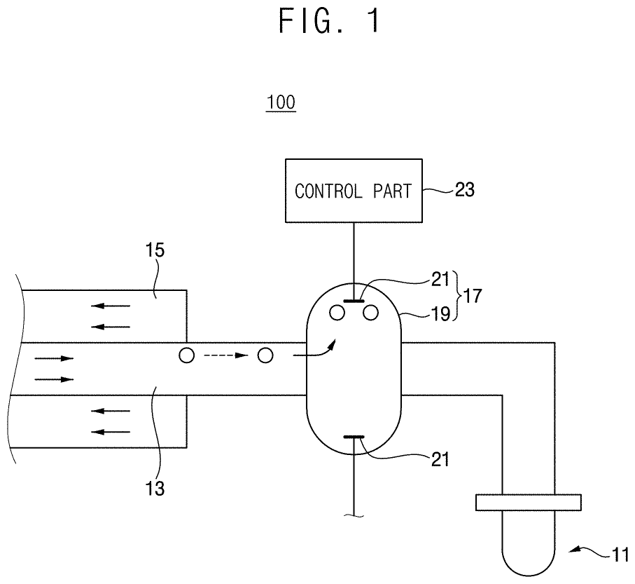

FIG. 1 is a schematic cross-sectional view illustrating an apparatus for supplying a chemical liquid in accordance with example embodiments of the invention.

The apparatus for processing a substrate 100 illustrated in FIG. 1 may be configured to provide a predetermined chemical liquid onto a substrate for manufacturing an integrated circuit device such as a semiconductor device or a display device. Referring to FIG. 1, the apparatus for processing a substrate 100 may include a device for supplying a solution. Here, the device for supplying a solution may include a chemical liquid supplying part 13, a fluid supplying part 15, a monitoring part 17 and a control part 23. Additionally, the apparatus for processing a substrate 100 may include a chemical liquid discharging part 11.

The chemical liquid discharging part 11 of the apparatus for supplying chemical liquid 100 may be configured to provide a solution having a first specific gravity onto the substrate. For example, the solution having the first specific gravity may be a chemical liquid. Examples of such chemical liquid having the first specific gravity may include, but not limited to, a photoresist, a developing solution, an etching solution or a cleaning solution. In example embodiments, the chemical liquid discharging part 11 may include a slit nozzle for coating the chemical liquid onto the substrate in a scan manner, or an ink jet head for coating the chemical liquid onto the substrate in a jetting manner.

The chemical liquid supplying part 13 may be configured to provide the chemical liquid to the chemical liquid discharging part 11. The chemical liquid supplying part 13 may include a chemical liquid storing part for storing the chemical liquid therein and a chemical liquid supplying line connecting the chemical liquid storing part to the chemical liquid discharging part 12 so as to supply the chemical liquid from the chemical liquid storing part to the chemical liquid discharging part 11.

The fluid supplying part 15 may be configured to allow the chemical liquid to have a temperature in accordance with process conditions while the chemical liquid is provided from the chemical liquid supplying part 13 to the chemical liquid discharging part 11. In example embodiments, the fluid supplying part 15 may increase or decrease the temperature of the chemical liquid such that the chemical liquid may have a desired temperature. For example, the fluid supplying part 15 may provide a fluid such as a liquid having a predetermined temperature around the chemical liquid supplied from the chemical liquid supplying part 13 to the chemical liquid discharging part 11. Here, the liquid provided from the fluid supplying part 15 may have a second specific gravity different fro the first specific gravity of the chemical liquid. In example embodiments, the liquid provided from the fluid supplying part 15 may include constant temperature water (CTW). Alternatively, the fluid supplying part 15 may provide other fluids suitable for adjusting the temperature of the chemical liquid.

If the fluid supplied from the fluid supplying part 15 is mixed with the chemical liquid provided from the chemical liquid supplying part 13, the composition of the chemical liquid may be changed, and thus failures may be caused in processes performed using such chemical liquid. In example embodiments, the fluid supplying part 15 and the chemical liquid supplying part 13 may have a double piping configuration. For example, the fluid supplying part 15 may substantially enclose a portion of the chemical liquid supplying part 13. Alternatively, the fluid supplying part 15 may pass through the chemical liquid supplying part 13.

According to example embodiments, a heat transfer may be accomplished between the fluid in the fluid supplying part 15 and the chemical liquid in the chemical liquid supplying part 13. Specifically, when the temperature of the chemical liquid is below the desired process temperature, a heat may be transferred to the chemical liquid from the fluid having a relatively high temperature. When the chemical liquid has a temperature higher than the desired process temperature, a heat may be moved to the chemical liquid from the fluid having a relatively low temperature. Therefore, the temperature of the chemical liquid provided from the chemical liquid supplying part 13 may be suitably adjusted by using the fluid supplying part 15.

In example embodiments, as described above, the fluid provided from the fluid supplying part 15 may have a second specific gravity different from the first specific gravity of the chemical liquid. For example, the second specific gravity may be substantially higher than the first specific gravity, or substantially lower than the first specific gravity. Since the fluid and the chemical liquid may have different specific gravities, respectively, the fluid and the chemical liquid may not be mixed even though the fluid flows into the chemical liquid supplying part 13.

In some example embodiments, the fluid may flow in a direction different from a direction where the chemical liquid flows. For example, when the chemical liquid flows along a first direction from the chemical liquid supplying part 13, the fluid from the fluid supplying part 15 may flow in a second direction different from the first direction. If the fluid flows along the first direction, the chemical liquid may have a relatively low temperature near the chemical liquid discharging part 11. When the chemical liquid and the fluid flow in the different directions, the chemical liquid may maintain the desired temperature.

According the above-described configurations of the apparatus for processing a substrate 100, the chemical liquid provided from the chemical liquid supplying part 13 may have the desired temperature using the fluid provided from the fluid supplying part 15 while preventing the fluid and the chemical liquid from being mixed. For example, the chemical liquid including the photoresist provided from the chemical liquid supplying part 13 may maintain the desired process temperature by the CTW provided from the fluid supplying part 15.

During providing the chemical liquid from the chemical liquid supplying part 13 and providing the fluid from the fluid supplying part 15, the fluid may flow into the chemical liquid supplying part 13 from the fluid supplying part 15. Particularly, when the apparatus for processing a substrate 100 has the double piping configuration in which the fluid supplying part 15 passes through the chemical liquid supplying part 13, the fluid may be leaked from the fluid supplying part 15 into the chemical liquid supplying part 13. Although the fluid has the second specific gravity different from the first specific gravity of the chemical liquid, a failure of a process performed using the chemical liquid may be caused if the fluid is partially mixed with the chemical liquid. Considering such a problem, the apparatus for processing a substrate 100 may include the monitoring part 17.

As illustrated in FIG. 1, the monitoring part 17 may sense and identify the fluid flowing into the chemical liquid supplying part 13 from the fluid supplying part 15. That is, the monitoring part 17 may monitor the leakage of the fluid from the fluid supplying part 15 into the chemical liquid supplying part 13. In this case, the monitoring part 17 may be disposed between the fluid supplying part 15 and the chemical liquid discharging part 11 or between the chemical liquid supplying part 13 and the chemical liquid discharging part 11.

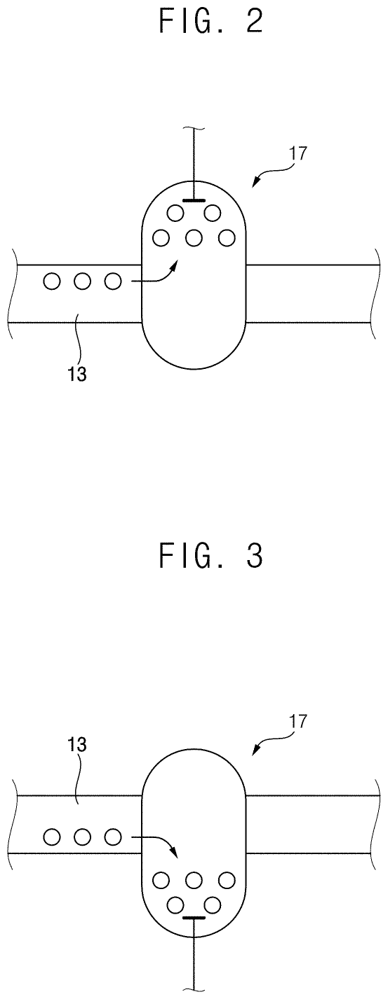

FIGS. 2 and 3 are schematically enlarged cross-sectional views illustrating a monitoring part of a device for supplying a solution in accordance with example embodiments of the invention.

In example embodiments, the monitoring part 17 may include a trapping part 19 and a sensing part 21. The trapping part 17 may be connected to the chemical liquid supplying part 13. The trapping part 17 may trap the fluid at a top portion thereof or at a bottom portion thereof using a difference between the specific gravity of the fluid and the specific gravity of the chemical liquid. As illustrated in FIG. 2, the fluid may be trapped at the top portion of the monitoring part 17 when the second specific gravity of the fluid is substantially smaller than the first specific gravity of the chemical liquid. In contrast, as illustrated in FIG. 3, the fluid may be trapped at the bottom potion of the monitoring part 17 when the second specific gravity is substantially greater than the first specific gravity. To trap such a fluid, the mentoring part 17 may have a substantial tube shape having a vertical axis longer than a horizontal axis.

Referring now to FIG. 1, the sensing part 21 may be configured to sense the fluid trapped in the trapping part 19. The sensing part 21 may be disposed at the top portion or the bottom portion of the trapping part 19 as the difference between the specific gravity of the fluid and the specific gravity of the chemical liquid. The sensing part 21 may include a resistive sensor. For example, when the chemical liquid provided from the chemical liquid supplying part 13 includes the photoresist having the first specific gravity and the fluid provided from the fluid supplying part 15 includes the CTW having the second specific gravity, the sensing part 21 may sense the fluid trapped at the top portion of the trapping part 19 (see FIG. 2). When the fluid provided from the fluid supplying part 15 includes other fluids having the second specific gravity smaller than the first specific gravity, the sensing part 21 may sense the fluid trapped at the bottom portion of the trapping part 19 (see FIG. 3).

Using the monitoring part 17 having the above-described configuration, the fluid leaked from the fluid supplying part 15 may not be mixed with the chemical liquid as well as the leakage of the fluid may be monitored.

The control part 23 of the device for supplying a solution may stop the supply of the chemical liquid from the chemical liquid supplying part 13. Further, the control part 23 may cease the discharge of the chemical liquid from the chemical liquid discharging part 11 onto the substrate. In example embodiments, the sensing part 21 may generate a sensing signal when the sensing part 21 sense the inflow of the fluid and may communicate the sensing signal to the control part 23. After the control part 23 receives the sensing signal from the sensing part 21, the control part 23 may cease the supply of the chemical liquid from the chemical liquid supplying part 13 and the discharge of the chemical liquid from the chemical liquid discharging part 11 when the control part 23 identify the fluid trapped in the trapping part 19. Therefore, it may be prevent the failure in the process performed using the chemical liquid even though the inflow of the fluid is identified while preventing the mixing of the fluid and the chemical liquid.

The apparatus for processing a substrate including the device for supplying a solution may be advantageously employed in manufacturing of an integrated circuit device such as a semiconductor device or a display device, in particular, an organic light emitting display (OLED) device or a quantum dot light emitting display (QLED) device.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A device for supplying a solution comprising:
a fluid supplying part configured to provide a fluid;
a chemical liquid supplying part configured to provide a chemical liquid having a specific gravity different from a specific gravity of the fluid; and
a monitoring port including a trapping part configured to trap the fluid flowing into the chemical liquid supplying part and a sensing part configured to sense an inflow of the fluid,
wherein a heat transfer is generated between the fluid and the chemical liquid, and
wherein the fluid is trapped at a top portion or a bottom portion of the trapping part in accordance with a difference between the specific gravity of the fluid and the specific gravity of the chemical liquid.

2. The device for supplying a solution of claim 1, wherein the fluid supplying part is configured to the fluid along a first direction and the chemical liquid is configured to provide the chemical liquid in a second direction different from the first direction.

3. The device for supplying a solution of claim 2, wherein the fluid supplying part is configured to partially enclose the chemical liquid supplying part or pass through the chemical liquid supplying part.

4. The device for supplying a solution of claim 1, further comprising a control part configured to stop a supply of the chemical liquid from the chemical liquid supplying part when the inflow of the fluid is identified by the monitoring part.

5. An apparatus for processing a substrate comprising:
a chemical liquid discharging part configured to discharge a chemical liquid having a first specific gravity onto a substrate;
a chemical liquid supplying part configured to provide the chemical liquid to the chemical liquid discharging part;
a fluid supplying part configured to provide a fluid having a second specific gravity different from the first specific gravity;
a chemical liquid supplying part configured to provide a chemical liquid having a second specific gravity different from the first specific gravity; and
a monitoring port including a trapping part configured to trap the fluid flowing into the chemical liquid supplying part and a sensing part configured to sense an inflow of the fluid,
wherein a heat transfer is generated between the fluid and the chemical liquid such that the chemical liquid has a desired temperature, and
wherein the fluid is trapped at a top portion or a bottom portion of the trapping part in accordance with a difference between the first specific gravity and the second specific gravity.

6. The apparatus for processing a substrate of claim 5, wherein the chemical liquid discharging part includes a slit nozzle configured to discharge the chemical liquid onto the substrate in a scan manner, or an ink jet head configured to discharge the chemical liquid onto the substrate in a jetting manner.

7. The apparatus for processing a substrate of claim 5, wherein the fluid is trapped at the top portion of the trapping part when the first specific gravity of the chemical liquid is greater than the second specific gravity of the fluid, and the sensing part is disposed at the top portion of the trapping part.

8. The apparatus for processing a substrate of claim 5, wherein the fluid is trapped at the bottom portion of the trapping part when the first specific gravity of the chemical liquid is smaller than the second specific gravity of the fluid, and the sensing part is disposed at the bottom portion of the trapping part.

9. The apparatus for processing a substrate of claim 5, wherein the chemical liquid supplying part is configured to provide the chemical liquid along a first direction and the fluid supplying part is configured to the fluid in a second direction different from the first direction.

10. The apparatus for processing a substrate of claim 5, wherein the fluid supplying part is configured to partially enclose the chemical liquid supplying part or pass through the chemical liquid supplying part.

11. The apparatus for processing a substrate of claim 5, wherein further comprising a control part configured to stop a supply of the chemical liquid when the inflow of the fluid is identified by the monitoring part.

12. The apparatus for processing a substrate of claim 5, wherein the control part is configured to stop a supply of the chemical liquid from the chemical liquid supplying part and a discharge of the chemical liquid from the chemical liquid discharging part.

13. A method of processing a substrate comprising:
providing a chemical liquid having a first specific gravity to a chemical liquid discharging part from a chemical liquid supplying part;
discharging the chemical liquid from the first specific gravity from the chemical liquid discharging part onto a substrate;
providing a fluid having a second specific gravity different from the first specific gravity from a fluid supplying part to the chemical liquid supplying part;
trapping the fluid flowing into the chemical liquid supplying part with a trapping part; and
sensing an inflow of the fluid in the trapping part with a sensing part,
wherein a heat transfer is generated between the fluid and the chemical liquid such that the chemical liquid has a desired temperature, and
wherein the fluid is trapped at a top portion or a bottom portion of the trapping part in accordance with a difference between the first specific gravity and the second specific gravity.

14. The method of processing a substrate of claim 13, wherein the chemical liquid discharging discharges the chemical liquid onto the substrate in a scan manner, or a jetting manner.

15. The method of processing a substrate of claim 13, wherein the fluid is trapped at the top portion of the trapping part when the first specific gravity of the chemical liquid is greater than the second specific gravity of the fluid, and the sensing part is disposed at the top portion of the trapping part.

16. The method of processing a substrate of claim 13, wherein the fluid is trapped at the bottom portion of the trapping part when the first specific gravity of the chemical liquid is smaller than the second specific gravity of the fluid, and the sensing part is disposed at the bottom portion of the trapping part.

17. The method of processing a substrate of claim 13, wherein the chemical liquid is provided along a first direction and the fluid is provided in a second direction different from the first direction.

18. The method of processing a substrate of claim 13, wherein the fluid supplying part partially encloses the chemical liquid supplying part or passes through the chemical liquid supplying part.

19. The method of processing a substrate of claim 13, further comprising stropping a supply of the chemical liquid when the inflow of the fluid is identified by the sensing part.

20. The method of processing a substrate of claim 13, wherein stopping a supply of the chemical liquid from the chemical liquid supplying part and a discharge of the chemical liquid from the chemical liquid discharging part are stopped.
